(19) United States
(12) Patent Application Publication
(10) Pub. No.: US 2013/0313718 A1
(43) Pub. Date: Nov. 28, 2013

(54) Substrates Comprising Integrated Circuitry, Methods Of Processing A Substrate Comprising Integrated Circuitry, And Methods Of Back-Side Thinning A Substrate Comprising Integrated Circuitry

(71) Applicants: Sony Varghese, Boise, ID (US); Andrew Carswell, Boise, ID (US); Kozaburo Sakai, Boise, ID (US); Andrey V. Zagrebelny, Eagan, MN (US); Wayne Huang, Boise, ID (US); Jin Lu, Boise, ID (US); Suresh Ramakrishnan, Boise, ID (US)

(72) Inventors: Sony Varghese, Boise, ID (US); Andrew Carswell, Boise, ID (US); Kozaburo Sakai, Boise, ID (US); Andrey V. Zagrebelny, Eagan, MN (US); Wayne Huang, Boise, ID (US); Jin Lu, Boise, ID (US); Suresh Ramakrishnan, Boise, ID (US)

(73) Assignee: MICRON TECHNOLOGY, INC., Boise, ID (US)

(21) Appl. No.: 13/480,341

(22) Filed: May 24, 2012

(51) Int. Cl. H01L 23/498; H01L 21/66; H01L 21/768

(52) U.S. Cl. 257/774; 438/667; 438/16; 257/E23.067; 257/E21.53; 257/E21.577

(57) ABSTRACT

A method of processing a substrate having integrated circuitry includes forming through-substrate vias partially through the substrate from a first side of the substrate. At least one through-substrate structure is formed partially through the substrate from the first substrate side. The at least one through-substrate structure extends deeper into the substrate than do the through-substrate vias. Substrate material is removed from a second side of the substrate to expose the through-substrate vias and the at least one through-substrate structure on the second substrate side. Additional implementations are disclosed. Integrated circuit substrates are disclosed independent of method of manufacture.

### TECHNICAL FIELD

Embodiments disclosed herein pertain to substrates comprising integrated circuitry and to methods of processing substrates comprising integrated circuitry.

### BACKGROUND

A through-substrate via is a vertical connection passing completely through a substrate comprising integrated circuitry. Through-substrate vias may be used to create 3D packages in 3D integrated circuits and are an improvement over other techniques such as package-on-package because the density of through-substrate vias may be substantially higher. Through-substrate vias provide interconnection of vertically aligned electronic devices through internal wiring that significantly reduces complexity and overall dimensions of a multi-chip electronic circuit.

Common through-substrate via processes include formation of through-substrate via openings through some, but not all, of the thickness of the substrate. A thin dielectric liner is then deposited to electrically insulate sidewalls of the through-substrate via openings. Adhesion and/or diffusion barrier material(s) may be deposited to line over the dielectric. The through-substrate via openings are then filled with conductive material. Substrate material is removed from the opposite side of the substrate from which the via openings were formed to expose the conductive material within the via openings.

It can be difficult to determine when sufficient material has been removed from the back-side of the substrate to expose the conductive material within the via openings. It is desirable to expose all such through-substrate vias without over-polishing them or the back-side material within which the vias are received.

### BRIEF DESCRIPTION OF THE DRAWINGS

FIG. 1 is a diagrammatic sectional view of a substrate fragment in process and in accordance with an embodiment of the invention.

FIG. 2 is a view of the FIG. 1 substrate fragment at a processing stage subsequent to that of FIG. 1.

FIG. 3 is a view of the FIG. 2 substrate fragment at a processing stage subsequent to that of FIG. 2.

FIG. 4 is a view of the FIG. 3 substrate fragment at a processing stage subsequent to that of FIG. 3.

FIG. 5 is a diagrammatic sectional view of a substrate fragment in process and in accordance with an embodiment of the invention.

FIG. 6 is a diagrammatic bottom view of a portion of the FIG. 5 substrate fragment.

FIG. 7 is a view of the FIG. 6 substrate fragment at a processing stage subsequent to that of FIG. 6.

FIG. 8 is a view of the FIG. 7 substrate fragment at a processing stage subsequent to that of FIG. 7.

FIG. 9 is a view of the FIG. 8 substrate fragment at a processing stage subsequent to that of FIG. 82.

FIG. 10 is a diagrammatic sectional view of a substrate fragment in process and in accordance with an embodiment of the invention.

### DETAILED DESCRIPTION OF EXAMPLE EMBODIMENTS

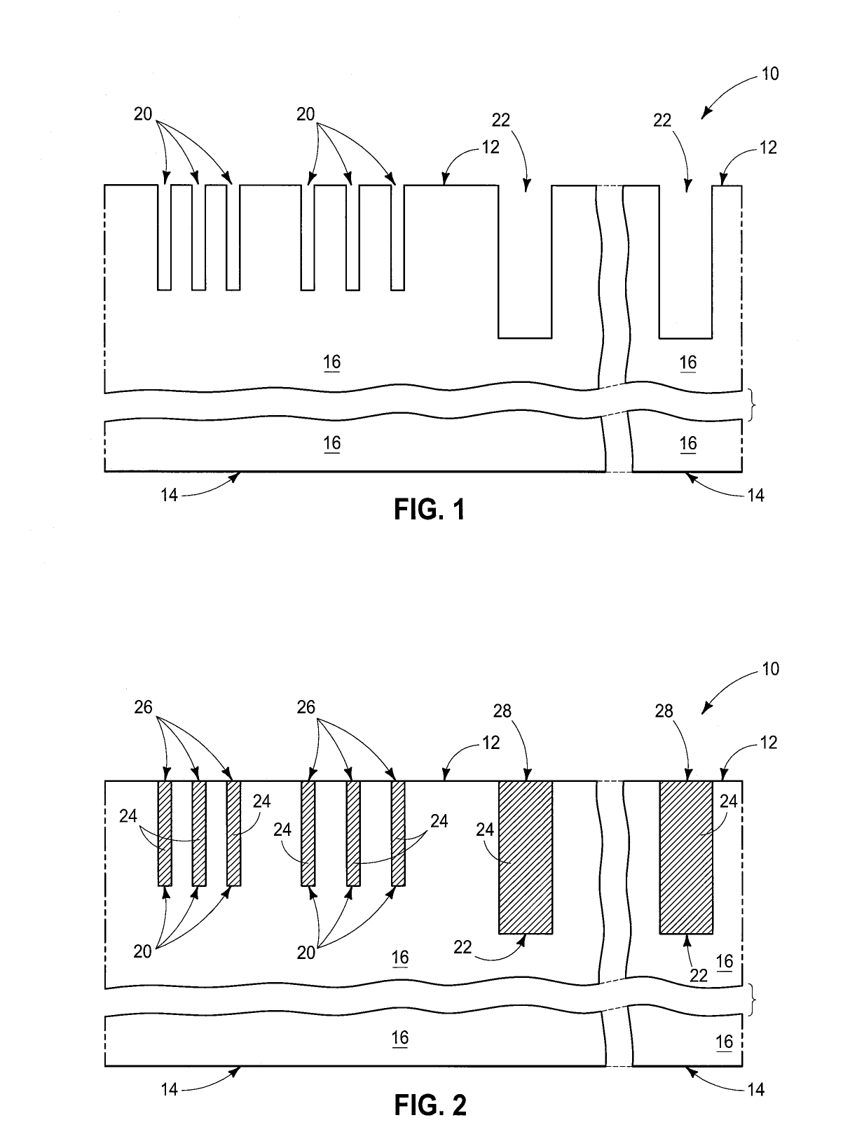

Embodiments of the invention encompass methods of processing substrates comprising integrated circuitry and substrates comprising integrated circuitry independent of method of manufacture. Example embodiments are described with references to FIGS. 1-10.

Referring to FIG. 1, a substrate fragment 10 comprises substrate material 16 and has opposing sides 12 and 14. Material 16 may be non-homogenous having multiple materials, regions, layers, and structures constituting integrated circuitry that has been fabricated or is in the process of being fabricated. Substrate 10 may comprise a semiconductor substrate. In the context of this document, the term “semiconductor substrate” or “semiconductive substrate” is defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above. For example, material 16 may comprise bulk semiconductor material, for example monocrystalline silicon. Material 16 may comprise a series of dielectric materials, for example proximate substrate side 12. Material 16 may comprise integrated circuit components (not shown), and which are not particularly germane to the disclosure. For convenience, substrate side 12 is referred to herein in some embodiments as a first or front side of substrate 10 and substrate side 14 is referred to herein in some embodiments as a second side or back-side of substrate 10.

Through-substrate via openings 20 have been formed partially through-substrate 10 from first substrate side 12. At least one through-substrate structure opening 22 has been formed partially through substrate 10 from first substrate side 12. Openings 22 extend deeper into substrate 10 than do through-substrate via openings 20. Openings 20 and 22 may be formed simultaneously (i.e., over a common time period) or formed separately. Openings 20 and 22 may be formed by chemical and/or physical means, with chemical etching, drilling, and laser ablation being a few examples. Further, if chemical etching, one or more suitable etching chemistries may be used to etch material 16.

Individual openings 20 and individual openings 22 may be of uniform respective width or non-uniform respective widths along their respective lengths. Further, through-substrate via openings 20 may be of the same or different size, shape, and/or depth relative one another, and through-substrate structure openings 22 may be of the same size, shape, and/or depth relative one another. In one embodiment, through-substrate structure openings 22 have maximum widths which are larger than all through-substrate via openings 20. By way of examples only, through-substrate via openings 20 may have a maximum width on substrate side 12 of from about 3 microns to about 5 microns and an example depth from first substrate side 12 of from about 40 microns to about 80 microns. An example thickness of substrate 10 from first substrate side 12 to second side substrate side 14 is from about 800 microns to 1,000 microns.

In one embodiment, through-substrate via openings 20 and through-substrate structure opening(s) 22 are formed by simultaneously etching of substrate material 16 to form such openings, and with the through-substrate structure opening(s) having maximum width(s) which is/are wider than that of through-substrate via openings 20 and which is/are etched deeper into the substrate, for example as shown. In one embodiment, the differing depths of openings 20 and 22 may result from the speed of etching of wider openings being greater than that of smaller openings. In short, a larger feature size may result in a deeper opening depth than results from a smaller feature size for a given etch process or processes. As an example, any of HBr, Cl₂, and CF₄ may be used to anisotropically etch into silicon selectively relative to SiO₂ to produce the structure of FIG. 1, with HBr resulting in a more selective etch than either of Cl₂ or CF₄, and Cl₂ more so than CF₄. Example anisotropic etching conditions include about 10 mTorr-100 mTorr, about 500 watts-800 watts, about 300 Volts (bias voltage), and substrate temperature of about 60° C.-80° C., with total gas flow rate being about 100 sccm-300 sccm. One or more inert gases, and/or O₂, may be included. The artisan may select other chemistries and/or conditions if etching into materials other than silicon. For example, SiO₂ and Si₃N₄ may be anisotropically etched with a chemistry comprising about 100 sccm CH₂F₂ and about 100 sccm CF₄ using the above conditions.

Referring to FIG. 2, through-substrate via openings 20 and the at least one through-substrate structure opening 22 have been filled with fill material 24. Fill material 24 may be homogenous or non-homogenous. As examples, fill material 24 may include dielectric and/or conductive liners and conductive central fill material (e.g., electrodeposited copper) and/or light transmissive/transparent material. Fill material 24 may be formed, for example, by one or more depositions which ultimately overfill(s) openings 20 and 22 followed by planarizing the fill material back at least to material 16 on first substrate side 12. Regardless, the above processing are but example embodiments of forming through-substrate vias 26 partially through substrate 10 from first substrate side 12 and of forming at least one through-substrate structure 28 partially through substrate 10 from first substrate side 12, with through-substrate structure(s) 28 extending deeper into the substrate than do through-substrate vias 26. Through-substrate vias have also been referred to in the art as through-silicon vias (TSVs). In this document, “through-substrate vias” (TSVs) encompass or are generic to through-silicon vias, and through-substrate vias include conductive and/or optically transmissive vias extending through substrate material regardless of whether any of that material is silicon. Further, through-substrate via openings and through-substrate structure openings are openings that are formed at least partially through the substrate and within which through-substrate vias or through-substrate structures, respectively, will be received.

In one embodiment, through-substrate vias 26 and through-substrate structure(s) 28 are formed at the same time (i.e., commensurately over the same period of time). In one embodiment, through-substrate vias 26 are formed to a uniform depth, and in one embodiment a through-substrate structure 28 has a maximum width that is greater than all those of through-substrate vias 26. In one embodiment, through-substrate vias 26 are formed to have the same maximum widths, and in one embodiment more than one through-substrate structure 28 is formed.

In one embodiment, the at least one through-substrate structure 28 is a dummy structure. In the context of this document, “dummy” or “dummy structure” refers to structure or function which is used to mimic a physical property of another structure (e.g., presence, or load carrying ability of an operative structure) and which may comprise a circuit inoperable electrical dead end (e.g., is not part of a current flow path of a circuit even if conductive). Openings in which dummy structures are formed may be considered as “dummy openings”. In one embodiment, the at least one through-substrate structure is a dummy structure and is not part of any current flow path in a finished circuitry construction of the substrate. In one embodiment, the at least one through-substrate structure 28 is an additional through-substrate via (i.e., is an “active” and operative through-substrate structure in the finished circuitry construction).

Substrate material is removed from the second side of the substrate to expose the through-substrate vias and the through-substrate structure(s) on the second substrate side. Such removal may occur by any suitable means, for example including mechanical and/or chemical methods, and whether existing or yet-to-be developed.

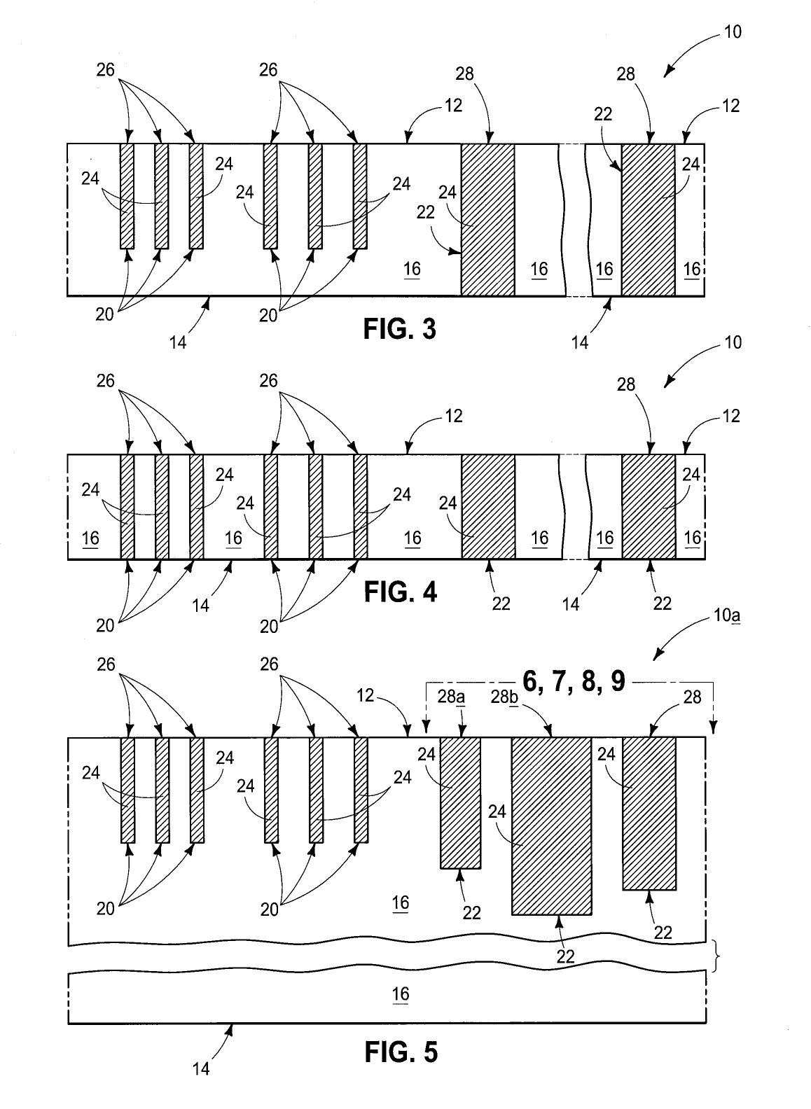

Referring to FIG. 3, substrate material 16 has been removed from second substrate side 14 to expose through-substrate structure opening(s) 22 having fill material 24 therein. In one ideal embodiment, the exposure of fill material 24 within through-substrate structure openings 22, and thereby exposure of through-substrate structure 28, is detected. In one embodiment, that detecting is used at least in part to determine proximity to the exposing of through-substrate vias 26. The example detecting may occur during the act of removing substrate material 16, or less ideal be conducted in batch examinations when the act of removing has been stopped at least temporarily. As an example, suitable machine vision equipment may be used during the removal action to detect presence and location of exposed through-substrate structures 28. Alternately as an example, presence of one or more components of fill material 24 may be chemically detected, for example by chemically analyzing polishing fluid used while polishing substrate side 14 for initial presence of fill material 24. Regardless, the example depths of through-substrate structures 28 and through-substrate vias 26 may be controlled and known values. Proximity to an example desired end point of removal of material 16 to the point of just exposing all through-substrate vias 26 might be more precisely controlled by detecting initial exposure of fill material 24 within a through-substrate structure opening 22. Such information may be used toward assuring both complete exposure of all through-substrate vias 26 and minimizing risk of over-removal of substrate material 16 after such exposure of through-substrate vias 26. In one embodiment, an earlier exposure of a deeper through-substrate structure(s) 28 is used at least in part to determine proximity to exposing of through-substrate vias 26.

The through-substrate via openings may be formed to respective non-uniform depths, or may be formed to a uniform depth. Regardless, where multiple through-substrate structures 28 are formed, such may be formed to a uniform depth which is deeper into the substrate than are the depths of the through-substrate vias openings (e.g., as shown in FIG. 2) or such may be formed to non-uniform depths. For example, FIG. 5 depicts an example alternate substrate fragment 10a. Like numerals from the above described embodiments have been used where appropriate, with some construction differences being indicated with suffixes “a” and “b”. FIG. 5 shows substrate fragment 10a having multiple different depth through-substrate structures 28, 28a, and 28b, and in some embodiments which may have one or more of the other features described above with respect to through-substrate structure 28 in the first-described embodiments with respect to FIG. 2. In one embodiment and as shown, FIG. 5 shows through-substrate structures 28, 28a, and 28b having different maximum widths. In one embodiment where simultaneous etching is used to form through-substrate structures 28, 28a, and 28b, such varying maximum width may be tailored to achieve desired different maximum depths within substrate material 16 that are each greater than one or more substrate depths of through-substrate vias 26. Regardless, in one embodiment varied depths of multiple through-substrate structures that extend deeper into the substrate than do the through-substrate vias may be used to progressively determine removal of substrate material 16 to a point of exposing through-substrate vias 26.

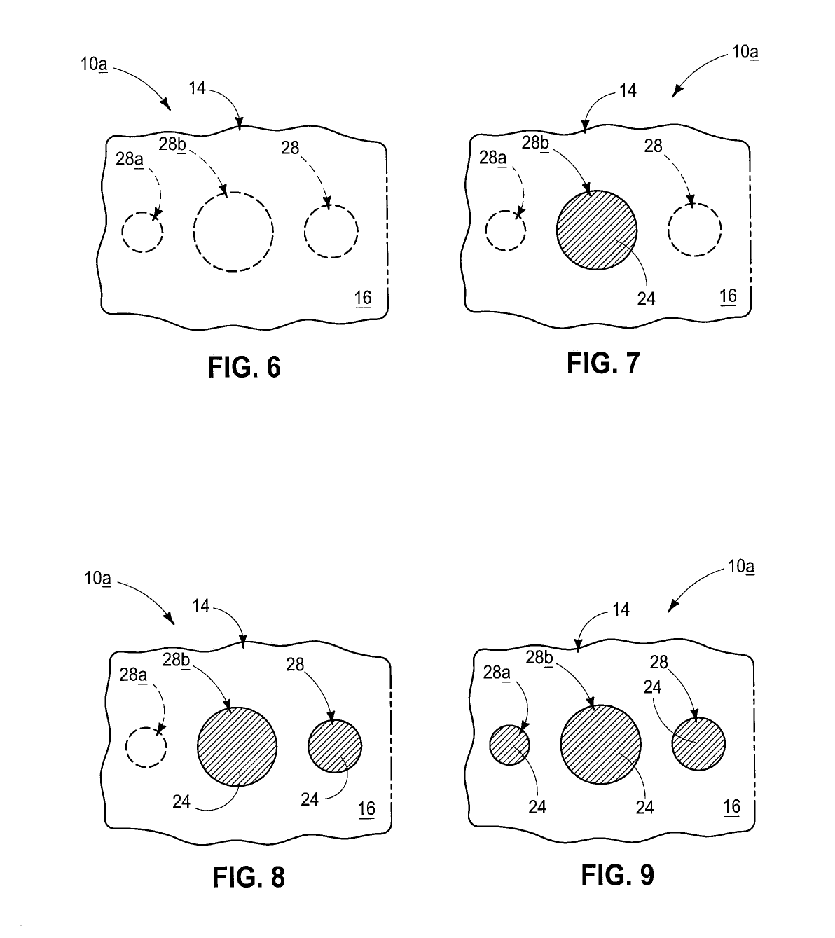

For example, FIGS. 6-9 sequentially show progression of removal of substrate material 16 from second substrate side 14. FIG. 6 shows no removal of material 16 or some removal of material 16 that is nevertheless insufficient to expose through-substrate structure 28b. FIG. 7 shows continued removal of substrate material 16 from substrate side 14 at least to the point of exposing through-substrate structure 28b but insufficient to expose through-substrate structures 28 and 28a. FIG. 8 shows continued removal of substrate material 16 inwardly from substrate side 14 sufficiently to at least expose through-substrate structure 28 but insufficient to expose through-substrate structure 28a. FIG. 9 shows further removal of substrate material 16 at least to the point of exposing through-substrate structure 28a. Accordingly, in one embodiment, monitoring of removal of the substrate material is progressively monitored by determining exposure of different depth through-substrate structures.

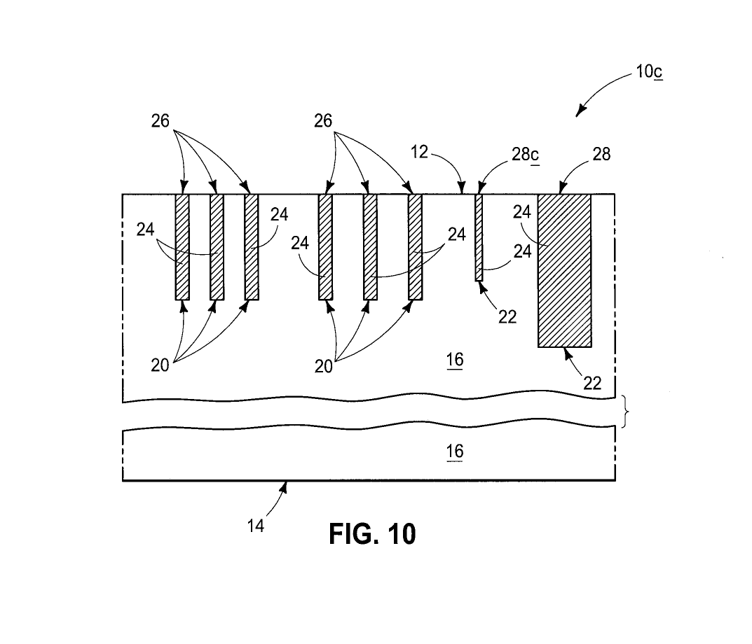

In one embodiment, another through-substrate structure is formed partially through the substrate from the first substrate side to extend into the substrate shallower than do all the through-substrate vias. The another through-substrate structure may be dummy or an additional through-substrate via. For example, FIG. 10 shows an alternate example substrate fragment 10c. Like numerals from the above described embodiments have been used where appropriate, with some construction differences being indicated with suffix “c”. Substrate 10c has another through-substrate structure 28c which has been formed partially through the substrate from first substrate side 12 to extend into substrate material 16 shallower than do all of through-substrate vias 26. In one embodiment, an opening in which through-substrate structure 28c is formed may result when etching through-substrate via openings 20 by making the opening for structure 28c narrower than the through-substrate via openings 20. More than one such structure 28c may be formed (not shown), and if so, such structures may be formed to different shallower depths than depth of through-substrate via openings 20. Any other attributes as described above may be used, for example combining the embodiments described with respect to FIGS. 5-9 with those described with respect to FIG. 10.

Embodiments of the invention encompass substrates comprising integrated circuitry, for example any of those described above. In one embodiment, such a substrate comprises a plurality of through-substrate vias extending partially through the substrate from one of opposing sides of the substrate. The substrate also includes at least one dummy through-substrate structure extending partially through the substrate from the one substrate side to a substrate depth that is deeper than depths to which the through-substrate vias extend. Other attributes as described above may be used independent of method.

### CONCLUSION

In some embodiments, a method of processing a substrate comprising integrated circuitry includes forming through-substrate vias partially through the substrate from a first side of the substrate. At least one through-substrate structure is formed partially through the substrate from the first substrate side. The at least one through-substrate structure extends deeper into the substrate than do the through-substrate vias. Substrate material is removed from a second side of the substrate to expose the through-substrate vias and the at least one through-substrate structure on the second substrate side.

In some embodiments, a method of processing a substrate comprising integrated circuitry includes simultaneously etching through-substrate via openings and at least one through-substrate structure opening partially through the substrate from a first side of the substrate. The at least one through-substrate structure opening has a wider maximum width than the through-substrate via openings and is etched deeper into the substrate than are the through-substrate via openings. The through-substrate via openings and the at least one through-substrate structure opening are filled with fill material. Substrate material is removed from a second side of the substrate to expose the at least one through-substrate structure opening having fill material therein. After exposing the fill material within the at least one through-substrate structure opening, substrate material is continued to be removed from the second substrate side and the fill material within the exposed at least one through-substrate structure opening is removed at least until exposing fill material within the through-substrate via openings.

In some embodiments, a method of processing a substrate comprising integrated circuitry includes providing a substrate comprising through-substrate vias that extend partially into the substrate from a front side of the substrate to a uniform substrate depth and comprising at least one through-substrate structure that extends partially into the front substrate side to a substrate depth deeper than the uniform substrate depth. The substrate is back-side thinned to expose the through-substrate vias using earlier exposure of the at least one through-substrate structure at least in part to determine proximity to exposing of the through-substrate vias.

In some embodiments, an integrated circuit substrate comprises a plurality of through-substrate vias extending partially through the substrate from one of opposing sides of the substrate. At least one dummy through-substrate structure extends partially through the substrate from the one substrate side to a substrate depth that is deeper than depths to which the through-substrate vias extend.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method of processing a substrate comprising integrated circuitry, comprising:
forming through-substrate vias partially through the substrate from a first side of the substrate;
forming at least one through-substrate structure partially through the substrate from the first substrate side, the at least one through-substrate structure extending deeper into the substrate than do the through-substrate vias; and
removing substrate material from a second side of the substrate to expose the through-substrate vias and the at least one through-substrate structure on the second substrate side.

2. The method of claim 1 wherein the through-substrate vias and the at least one through-substrate structure are formed at the same time.

3. The method of claim 1 wherein the at least one through-substrate structure comprises an additional through-substrate via.

4. The method of claim 1 wherein the at least one through-substrate structure is dummy.

5. The method of claim 1 comprising forming another through-substrate structure partially through the substrate from the first substrate side, the another through-substrate structure extending into the substrate shallower than do all said through-substrate vias.

6. The method of claim 1 wherein the through-substrate vias are formed to a uniform depth.

7. The method of claim 6 comprising forming another through-substrate structure partially through the substrate from the first substrate side, the another through-substrate structure extending into the substrate shallower than the uniform depth.

8. The method of claim 7 wherein the at least one through-substrate structure comprises an additional through-substrate via.

9. The method of claim 7 wherein the at least one through-substrate structure is dummy.

10. The method of claim 1 wherein the at least one through-substrate structure has a maximum width that is greater than all those of said through-substrate vias.

11. The method of claim 10 comprising forming said through-substrate vias to have the same maximum widths.

12. The method of claim 1 comprising forming more than one of said through-substrate structures.

13. The method of claim 1 comprising using earlier exposure of the at least one through-substrate structure at least in part to determine proximity to exposing of the through-substrate vias.

14. The method of claim 13 comprising forming multiple of said through-substrate structures to at least two different depths into the substrate, progressively monitoring progress of said removing of substrate material at least in part by determining exposure of said different depth through-substrate structures.

15. The method of claim 14 wherein said determining occurs while removing said substrate material.

16. A method of processing a substrate comprising integrated circuitry, comprising:
simultaneously etching through-substrate via openings and at least one through-substrate structure opening partially through the substrate from a first side of the substrate, the at least one through-substrate structure opening having a wider maximum width than the through-substrate via openings and being etched deeper into the substrate than are the through-substrate via openings;
filling the through-substrate via openings and the at least one through-substrate structure opening with fill material;
removing substrate material from a second side of the substrate to expose the at least one through-substrate structure opening having fill material therein; and
after exposing the fill material within the at least one through-substrate structure opening, continuing removing the substrate material from the second substrate side and removing the fill material within the exposed at least one through-substrate structure opening at least until exposing fill material within the through-substrate via openings.

17. The method of claim 16 detecting exposure of the fill material within the at least one through-substrate structure opening.

18. The method of claim 17 comprising using said detecting at least in part to determine proximity to exposing of the fill material within the through-substrate via openings.

19. The method of claim 16 wherein the at least one through-substrate structure is dummy.

20. The method of claim 16 comprising simultaneously etching multiple through-substrate structure openings to multiple different depths and different wider widths than the through-substrate via openings using said different wider widths to determine said multiple different depths.

21. A method of back-side thinning a substrate comprising integrated circuitry, comprising:
providing a substrate comprising through-substrate vias that extend partially into the substrate from a front side of the substrate to a uniform substrate depth and comprising at least one through-substrate structure that extends partially into the front substrate side to a substrate depth deeper than the uniform substrate depth; and
back-side thinning the substrate to expose the through-substrate vias using earlier exposure of the at least one through-substrate structure at least in part to determine proximity to exposing of the through-substrate vias.

22. The method of claim 21 wherein the at least one through-substrate structure is dummy.

23. The method of claim 22 wherein the at least one through-substrate structure is not part of any current flow path in a finished circuitry construction of the substrate.

24. A substrate comprising integrated circuitry, comprising:
a plurality of through-substrate vias extending partially through the substrate from one of opposing sides of the substrate; and
at least one dummy through-substrate structure extending partially through the substrate from the one substrate side to a substrate depth that is deeper than depths to which the through-substrate vias extend.

25. The method of claim 24 wherein the at least one dummy through-substrate structure is not part of any current flow path in a finished circuitry construction of the substrate.

26. The method of claim 24 comprising another dummy through-substrate structure extending partially through the substrate from the one opposing substrate side, the another dummy through-substrate structure extending into the substrate shallower than do all said through-substrate vias.

27. The method of claim 24 wherein the through-substrate vias extend partially into the substrate to a uniform depth.

28. The method of claim 24 wherein the at least one dummy through-substrate structure has a maximum width that is greater than all those of said through-substrate vias.
